(19) United States
(12) Patent Application Publication
(10) Pub. No.: US 2016/0274442 A1
(43) Pub. Date: Sep. 22, 2016

(54) Extensive Light-Emitting Element for a Flash Apparatus, Flash Apparatus and Electronic Device Comprising a Flash Apparatus

(71) Applicant: OSRAM OLED GMBH, Regensburg (DE)

(72) Inventors: Andreas Rausch, Regensburg (DE); Kilian Regau, Regensburg (DE); Thorsten Vehoff, Regensburg (DE)

(73) Assignee: OSRAM OLED GmbH, Regensburg (DE)

(21) Appl. No.: 15/033,924

(22) PCT Filed: Nov. 12, 2014
(86) PCT No.: PCT/EP2014/074382

§ 371 Date: May 3, 2016

(30) Foreign Application Priority Data
Nov. 13, 2013 (DE) 10 2013 112 489.5

(51) Int. Cl. G03B 15/05; H01L 27/32; H04N 5/225

(52) U.S. Cl. CPC G03B 15/05; H04N 5/2256; H01L 27/3234; G03B 2215/0567

(57) ABSTRACT

An extensive light-emitting element, a flash apparatus and an electronic device having a flash apparatus are disclosed. In an embodiment the extensive light-emitting element includes at least one OLED, wherein the OLED comprises an organic light-emitting layer sequence arranged between a substrate and a covering layer, and wherein the organic light-emitting layer sequence comprises a recess in a region of the extensive light-emitting element.

This patent application is a national phase filing under section 371 of PCT/EP2014/074382, filed Nov. 12, 2014, which claims the priority of German patent application 10 2013 112 489.5, filed Nov. 13, 2013, each of which is incorporated herein by reference in its entirety.

### TECHNICAL FIELD

The invention relates to an extensive light-emitting element for a flash apparatus, a flash apparatus and an electronic device comprising a flash apparatus.

### BACKGROUND

Flash photography generally proceeds in portable electronic devices such as mobile data processing and/or telecommunication devices (for example, smart phones or tablet computers) by means of a flash integrated into said device, wherein in a majority of cases LEDs are used. In portable devices, integrated flashes have maximally space-saving dimensions, whereby the flash achieves approximately the effect of a point light source. One disadvantage of a point light source is, for example, non-homogeneous illumination of the target area to be exposed.

In general, the point light source emits a strong flash and thereby causes hard shadows on the photo and strong glare for the people being photographed.

So as not to place excessive demands on the limited battery charge of the portable electronic devices as a result of the high energy consumption of the internal flash, on photographing with flash generally the flash power is reduced and the sensitivity of the camera chip is increased. The increase in sensitivity of the camera chip disadvantageously gives rise to significant image noise and thus lower image quality than for photographs taken in daylight without flash.

External flash devices offer a partial remedy for this, these being as extensive or large as possible and having their own battery. However, a disadvantageous effect is that external flashes are generally unwieldy and therefore, to impair the convenience of the portable electronic device as little as possible, need to be removed from the portable electronic device when not in use. Furthermore, external flashes impair the esthetic appearance of the portable electronic devices.

### SUMMARY

Embodiments of the invention provide an extensive light-emitting element for an improved flash apparatus, an improved flash apparatus and an electronic device comprising an improved flash apparatus.

According to one configuration, the extensive light-emitting element comprises at least one OLED, which comprises an organic light-emitting layer sequence. The organic light-emitting layer sequence is arranged between a substrate and a covering layer. Furthermore, at least the organic light-emitting layer sequence comprises a recess in a region of the extensive light-emitting element.

The extensive light-emitting element serves in particular as a flash and advantageously comprises at least one OLED. The extensive nature of the light-emitting element results in a larger emission surface than in the case of a small flash (LED as point light source). As a result of the extensively dimensioned light-emitting element, the glare factor affecting the person to be photographed is reduced relative to a point light source, since the required light output of the flash is advantageously distributed over the larger area of the light-emitting element. Flash emission from a preferably maximally large area advantageously reduces hard shadows on the photographed images.

An extensive light-emitting element, in particular an OLED, meets the requirements of a flash for achieving minimum illuminance of a target area to be photographed. Preferably, OLEDs operated for a short time with a high current are used for this purpose. Thus, for example, if a target area of constant size is illuminated alternately by an extensive OLED and by a point light source (LED flash), in the case of the point light source the illuminance falls at the edge of the illuminated region to, for example, 10% of the illuminance at the center. In the case of the OLED, a distinctly higher illuminance is achieved at the edge, for example, 40% of the illuminance at the center. In order, for example, to achieve a default value for illumination of the edge region of 10%, the OLED thus makes it possible to illuminate a larger target region. The greater the dimensions of a portable electronic device, for example, in the case of a tablet computer, the greater the achievable emission area of an extensive light-emitting element mountable thereon and the illuminance thereby achievable. For a predetermined minimum illuminance, it is advantageously possible further to reduce the light output emitted per unit area, which further reduces the glare factor.

The recess at least in the organic light-emitting layer sequence makes it possible to arrange the extensive light-emitting element as a flash on an electronic device with integrated camera without covering up the integrated camera. The extensive light-emitting element is preferably applied with the substrate or the covering layer onto the electronic device.

The covering layer, for example, comprises glass or a non-transparent metallic material. The substrate is transparent or non-transparent for light generated in the organic light-emitting layer sequence.

If the recess does not extend through the substrate and the covering layer, an objective of a camera positioned under the recess is advantageously protected from external influences by the extensive light-emitting element. Furthermore, no additional process steps have to be used to cut a recess for an objective into the substrate and into the covering layer. A separate objective protection is thereby advantageously not necessary.

For example, the substrate terminates the extensive light-emitting element in the emission direction. Alternatively, the covering layer may also terminate the extensive light-emitting element in the emission direction.

If the substrate terminates the extensive light-emitting element in the emission direction, the extensive light-emitting element is a bottom emitter; if the covering layer terminates the extensive light-emitting element in the emission direction, the extensive light-emitting element is a top emitter.

The OLED may comprise a non-luminous region adjacent the recess in the region around the recess next to the organic light-emitting layer sequence. This non-luminous region advantageously takes the form of encapsulation of the organic light-emitting layer sequence, to protect the organic layer sequence from diffusion. The non-luminous region may take the form of a layer between the substrate and the covering layer, is located between the recess and the organic light-emitting layer sequence and preferably directly adjoins the organic light-emitting layer sequence. Furthermore, an encapsulation layer may additionally be applied between the organic light-emitting layer sequence and the covering layer.

According to one configuration of the extensive light-emitting element, the recess extends through the substrate, the organic light-emitting layer sequence and the covering layer of the OLED.

According to one configuration of the extensive light-emitting element, the recess is larger in the substrate and in the organic light-emitting layer sequence than in the region of the covering layer, or the recess in the covering layer and in the organic light-emitting layer sequence is larger than the recess in the region of the substrate, such that a sub-region of the covering layer or of the substrate adjoining the recess in the covering layer or the substrate is not covered by the organic light-emitting layer sequence.

The recess in the substrate and in the organic light-emitting layer sequence is advantageously larger than the recess in the covering layer, wherein a sub-region of the covering layer adjoining the recess is not covered by the organic light-emitting layer sequence. Alternatively, the recess in the covering layer and in the organic light-emitting layer sequence may also advantageously be larger than the recess in the substrate, wherein a sub-region of the substrate adjoining the recess is not covered by the organic light-emitting layer sequence. In other words, either the covering layer or the substrate terminates the extensive light-emitting element in the emission direction. Accordingly, in the recess the side faces of the covering layer and of the organic light-emitting layer sequence do not terminate flush with the side faces of the substrate, or the side faces of the substrate and of the organic light-emitting layer sequence do not terminate flush with the side faces of the covering layer within the recess. Advantageously, a smaller proportion of light which is coupled out through the side faces of the covering layer and the organic light-emitting layer sequence facing the recess or of the substrate and the organic light-emitting layer sequence thereby enters the recess as troublesome stray radiation. The reduction in stray radiation in the recess advantageously improves image capture quality through the recess.

According to one configuration of the extensive light-emitting element, within the recess the sub-region of the covering layer or the sub-region of the substrate is covered with a layer which is reflective or absorbing.

The sub-region of the covering layer or the sub-region of the substrate which is not covered by the organic light-emitting layer sequence is advantageously covered with a reflective or absorbing layer. Thus, light which is coupled out through the side faces of the substrate or the covering layer facing the recess is reflected or absorbed on incidence on the reflective or absorbing layer, whereby the proportion of stray radiation in the recess is advantageously further reduced. This advantageously improves the quality of photographs taken, for example, by means of a camera through the recess.

According to one configuration of the extensive light-emitting element, the substrate or the covering layer follows the organic light-emitting layer sequence in the emission direction, and the side faces of the substrate or of the covering layer, which face the recess, are beveled.

The substrate/covering layer terminating the extensive light-emitting element in the emission direction comprises side faces which face the recess and are advantageously beveled. As a result of the beveling, which is preferably inclined relative to the emission direction, the proportion of the radiation coupled out through the side faces is emitted to a greater extent in the direction away from the recess. In this way, the proportion of stray radiation in the recess is additionally reduced, and it is thereby furthermore possible to reduce the size of the recess in the substrate or in the covering layer, such that the sub-region of the covering layer or of the substrate not covered by the organic light-emitting layer sequence may likewise be reduced and the emission area of the OLED may advantageously be enlarged.

According to one configuration of the extensive light-emitting element, a non-transparent cover is applied at least to side faces of the extensive light-emitting element which face the recess.

The non-transparent cover advantageously covers at least the side faces of the extensive light-emitting element facing the recess, such that no radiation is emitted through the side faces into the recess, wherein the non-transparent cover takes the form of a layer or, in the case of a round recess, preferably of a ring. The recess in this case preferably extends through the substrate, the organic light-emitting layer sequence and the covering layer. The non-transparent cover may extend vertically beyond the side faces in the emission direction and rests partly on the extensive light-emitting element. It is then possible for the extensive light-emitting element, for example, to comprise an OLED with a substrate and a covering layer, wherein the non-transparent cover rests advantageously partly on the substrate or partly on the covering layer and partly covers the substrate or the covering layer preferably in the vicinity of the recess. Alternatively, the non-transparent cover does not project vertically beyond the recess and at least partly covers the inner side faces of the recess. Advantageously, the recess has the same size in the substrate, in the organic light-emitting layer sequence and in the covering layer. This allows the size of the recess to be minimized and enables a maximum possible emission area for the light-emitting element.

According to at least one embodiment of the extensive light-emitting element, a light sensor is arranged in a further recess, wherein the further recess extends at least through the organic light-emitting layer sequence in one region of the extensive light-emitting element.

The further recess advantageously makes it possible to use, in addition to the flash of the extensive light-emitting element, an internal flash of a camera which is integrated, for example, into an electronic device for which the extensive light-emitting element serves as flash. The two flashes are advantageously superimposed during flash triggering. Synchronization electronics are, for example, advantageously connected with a light sensor and detect the internal flash of a camera by means of the light sensor and trigger the flash of the extensive light-emitting element. For an extensive light-emitting element which is mounted on an electronic device, the light sensor is advantageously mounted within a further recess in the extensive light-emitting element at the position of the internal camera flash. The further recess may, for example, extend only through the organic light-emitting layer sequence or through the substrate, the organic light-emitting layer sequence and the covering layer. Within the further recess, the light sensor may be integrated into the substrate or the covering layer, if the further recess extends only through the organic light-emitting layer sequence. If the further recess extends through the organic light-emitting layer sequence, the substrate and the covering layer, the further recess may, for example, comprise a potting compound into which the light sensor is integrated.

According to at least one embodiment of the extensive light-emitting element, at least one light sensor is arranged on a surface of the organic light-emitting layer sequence, wherein the at least one light sensor faces away from an emission direction of the extensive light-emitting element.

According to at least one embodiment of the extensive light-emitting element, the at least one light sensor wholly or partially covers the surface of the organic light-emitting layer sequence facing away from the emission direction of the extensive light-emitting element.

The light sensor may advantageously be integrated into or applied to the organic light-emitting layer sequence as an organic light sensor as early as during production thereof. The light sensor is formed over, or integrated into, at least part, preferably all of a surface of the organic light-emitting layer sequence. The surface of the organic light-emitting layer sequence with the light sensor arranged thereon or integrated therein faces away from the emission direction of the extensive light-emitting element. This in particular enables detection of an internal flash of a camera of the electronic device by the light sensor irrespective of the manufacturer of the electronic device, since the light sensor does not have to be positioned exactly over the internal camera flash. The extensive light-emitting element serves as a flash for the camera and may thus be synchronized with an internal camera flash. The extensive light-emitting element may to this end, on the side of the electronic device comprising the internal flash, be mounted directly onto the electronic device or mounted on a housing enclosing the electronic device. To this end, it is necessary for the housing to be transparent to light between the electronic device and the light sensor.

According to at least one embodiment of the flash apparatus with the extensive light-emitting element, the flash apparatus comprises a housing, wherein the extensive light-emitting element is arranged on an emission side of the housing, and wherein the housing also comprises a recess in the region of the recess in the extensive light-emitting element.

The housing may advantageously be “compact’ in form, “compact” here meaning that the housing may, for example, enclose a portable electronic device in such a manner as to provide protection and to conform in shape to the device. Furthermore, functional characteristics, operation and handling as well as optical and esthetic properties such as, for example, the design of a portable electronic device are advantageously not impaired by the housing applied thereto but rather are advantageously improved and optimized.

On an outer side of the housing, which is preferably located on a back of the portable electronic device advantageously enclosed by the housing and which preferably faces away from the electronic device, the housing comprises an extensive light-emitting element. The light-emitting element is advantageously applied over a maximally large area, preferably over the entire area of this outer side. Hereinafter, this outer side is referred to as an emission area of the housing. A recess for a camera integrated into the portable electronic device is advantageously introduced into the housing. In particular, the camera is located on the back of the portable electronic device. The extensive light-emitting element covering the emission area of the housing likewise comprises a recess at the position of the recess in the housing. This makes it possible to enclose an electronic device with a camera by a housing without covering up the integrated camera.

The extensive light-emitting element and the housing may advantageously be very flat, whereby advantageously no significant modification of the shape factors of the electronic device takes place.

According to at least one embodiment of the flash apparatus, said flash apparatus comprises synchronization electronics with at least one interface, wherein the synchronization electronics are enclosed in the housing, and at least one energy storage unit, which is enclosed in the housing.

On insertion of an electronic device into the housing, the electronic device is advantageously connected with the synchronization electronics via an interface. The interface advantageously serves to transmit signals between the electronic device and the light-emitting element.

Furthermore, the housing may comprise a charging interface for charging the energy storage unit of the flash apparatus. The charging interface is preferably a USB port. The USB port of the charging interface may advantageously also be used to connect the synchronization electronics to an external control device, for example, a computer. It is likewise possible to control the electronic device inserted into the housing via an external control device. Furthermore, an internal energy storage unit of the electronic device inserted into the housing may also be charged via the USB charging interface, in addition to the energy storage unit of the flash apparatus.

The synchronization electronics as well as the at least one interface and the energy storage unit may advantageously be enclosed in a side region of the housing, which is preferably located laterally next to the inserted electronic device, in order to enlarge the thickness of the housing as far as possible only slightly by the light-emitting element located thereon relative to the thickness of the electronic device. For example, the housing advantageously comprises a hinge laterally adjoining the emission area of the housing, wherein a cover face of the housing may advantageously be folded over using the hinge to cover up a front of the electronic device. In order not to increase the thickness of the housing by the synchronization electronics and the energy storage unit, these are preferably incorporated into the housing together with the interface within the hinge.

For improved short-term high-current operation of the OLED during triggering of the flash, it is advantageously possible to use a supercapacitor (supercap) in the energy storage unit in addition to the battery or instead of the battery. The supercapacitor advantageously enables rapid discharge of high currents, wherein the charging profile of the supercapacitor may advantageously proceed slowly or very fast depending on the application. This allows lower current loading of the internal energy storage unit of the electronic device and/or of the energy storage unit of the flash apparatus by the light-emitting element during triggering of the flash. The supercapacitor may advantageously be charged by the internal energy storage unit of the electronic device and/or by the energy storage unit of the flash apparatus when the light-emitting element is switched off.

According to at least one embodiment of the flash apparatus, the housing takes the form of a case or protective sleeve.

An embodiment of the housing of the flash apparatus as a case or protective sleeve, for example, for mobile telephones or tablet computers preferably has a shape as far as possible ideally conformed to the electronic device, such that advantageously the contours characterizing the device are identifiable even with the flash apparatus attached. In this way, the design of the electronic device is advantageously likewise reproduced by the flash apparatus. It is furthermore, for example, possible to use the OLED in a mirroring mode.

The OLED may advantageously comprise an electrode on its side facing away from the emission direction, which electrode consists of a metallic material and is thus of mirroring configuration. The OLED may therefore advantageously be used when switched off as a mirror, for example, a make-up mirror. When switched on, the light-emitting element may advantageously be used as a torch or mood light, or as a visual call indicator. It is furthermore, for example, possible to use the mirror effect to check the position of an object to be photographed, such as for instance in the case of a self-portrait, without a second camera being needed on the emission side of the OLED.

According to at least one embodiment of the flash apparatus, the housing may be opened and closed by folding, wherein the emission side of the housing is arranged with the extensive light-emitting element mounted thereon on a housing lid plate, wherein the lid plate may be folded round on closure, such that when the housing is closed the extensive light-emitting element is located on the inside of the closed housing.

When a housing is open, the foldable lid plate thereof advantageously forms the emission side of the housing with the extensive light-emitting element mounted thereon and in this case likewise comprises a recess, as does the part of the housing directly adjacent below the lid plate and located between the lid plate and the back of the electronic device. The extensive light-emitting element is advantageously applied to the emission side of the lid plate, such that the emission direction faces away from the electronic device when the housing is open. On closure of the housing, the lid plate is advantageously folded round preferably by approximately 360°, such that the side of the lid plate comprising the light-emitting element faces the electronic device after folding. This means that, when the housing is closed, advantageously both the device and the light-emitting element are protected from external influences.

According to at least one embodiment of the flash apparatus, the housing may be closed and opened by folding, wherein a further extensive light-emitting element is located on a lid of the housing. The lid may be folded round on opening of the housing, such that the lid face of the lid is oriented in the emission direction of the emission side of the housing.

In addition to the emission side of the housing, on the back of the electronic device it is advantageously possible for the further extensive light-emitting element to be mounted on the lid of the housing in such a way that, when the housing is closed, the lid preferably covers the front of the electronic device and protects it from external influences. The further extensive light-emitting element then faces away from the electronic device and is applied to the outside of the lid. On opening the housing, the lid is advantageously folded round by 180°, whereby the emission area of the housing is greatly enlarged by the further extensive light-emitting element, preferably doubled. The further extensive light-emitting element is preferably an extensive light-emitting element as already described, however the further extensive light-emitting element preferably does not comprise any recesses.

According to at least one embodiment of the flash apparatus, the synchronization electronics are set up to control the at least one energy storage unit and to synchronize at least one camera inserted into the housing with the flash apparatus.

The synchronization electronics advantageously synchronize photographing by the camera of the electronic device with the triggering of the flash on the light-emitting element.

The synchronization electronics advantageously regulate the state of charge of the energy storage unit, which in particular comprises a rechargeable battery.

Depending on ambient brightness, the available state of charge of the energy storage unit may, for example, be used in a maximally energy-saving manner.

According to at least one embodiment of the flash apparatus, an audio signal pattern and/or a digital signal pattern may be received via the at least one interface of the synchronization electronics to synchronize the flash apparatus.

To connect the synchronization electronics with the electronic device, the interface may advantageously comprise a plug connector, wherein the plug connector may be specific to or independent of the manufacturer. The plug connector is, for example, a jack plug or audio jack in particular with a diameter of 3.5 mm. On insertion of the electronic device into the housing, the plug connector is, for example, connected to the interface of the electronic device. An advantageously defined signal pattern preferably detectable by the synchronization electronics may thus advantageously be used to synchronize the electronic device with the light-emitting element. The defined signal pattern may advantageously be generated by the software of the electronic device. The audio signal pattern is preferably not in the range audible to humans or is digitally superimposed on the audio signal.

In general, use of an inexpensive, manufacturer-independent interface is possible.

According to one configuration, the electronic device comprises a flash apparatus according to one of the embodiments. Furthermore, the electronic device comprises a mobile data processing and/or telecommunication device, which comprises an integrated camera.

### BRIEF DESCRIPTION OF THE DRAWINGS

Further features, configurations and convenient aspects are revealed by the following description of the exemplary embodiments of the flash apparatus in conjunction with the figures.

FIGS. 1A to 1C show a schematic side view of an extensive light-emitting element on an electronic device with different embodiments of the recess.

FIGS. 2A, 3A and 4 show the flash apparatus in an external view with three different embodiments of the housing.

FIGS. 2B and 3B show an electronic device with a flash apparatus according to FIGS. 2A and 3A in a side view onto the housing.

FIGS. 5 and 6 show the extensive light-emitting element with a light sensor with two different embodiments of the light sensor.

### DETAILED DESCRIPTION OF ILLUSTRATIVE EMBODIMENTS

Identical or identically acting elements are provided with identical reference numerals in each of the figures. The components illustrated in the figures and the size ratios of the components to one another should not be regarded as to scale.

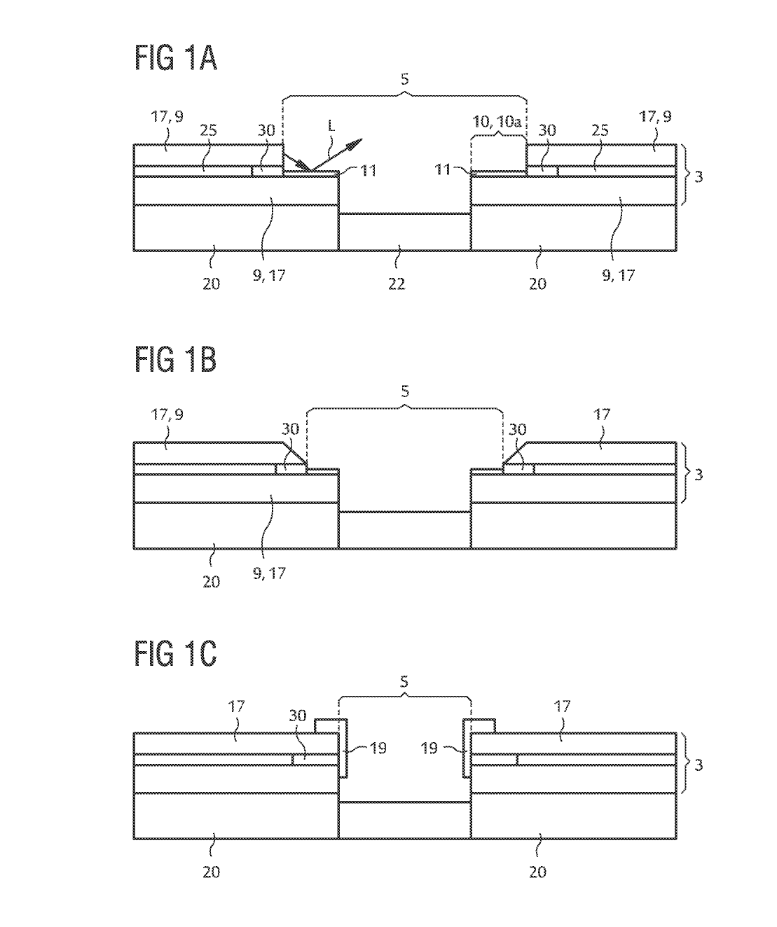

FIG. 1A shows a schematic side view of the extensive light-emitting element (i.e. having an extended surface area) 3 on an electronic device 20. The extensive light-emitting element 3 comprises an organic light-emitting layer sequence 25, a substrate 17 and a covering layer 9. The covering layer 9 is, for example, a cover glass transparent to light, which encapsulates the organic light-emitting layer sequence 25. The recess 5 extends at the position of a camera 22 of an electronic device 20, to the back of which the extensive light-emitting element 3 with the covering layer 9 is applied, wherein the substrate 17 terminates the extensive light-emitting element 3 in the emission direction on a side remote from the electronic device 20. Alternatively, the covering layer 9 may also comprise a non-transparent metallic material. The substrate 17 is preferably transparent.

Adjacent the recess 5, laterally next to the organic light-emitting layer sequence 25, a non-luminous region 30 is arranged on a covering layer 9, which region is located between the layer sequence 25 and the recess 5 and does not itself emit light. The non-luminous region 30 may advantageously comprise organic materials.

Within the recess 5, a sub-region 10 of the covering layer 9 is not covered by the organic layer sequence 25 and the non-luminous region 30. The sub-region 10 is covered by a layer 11, which is reflective or absorbing and the side faces of which terminate flush with the side faces of the recess 5 in the covering layer 9.

Luminous radiation L, which is coupled out through the side faces of the substrate 17 facing the recess 5, is reflected or absorbed by the layer 11. Since the recess 5 is very wide compared with the height of the OLED 3, the proportion of stray radiation L outcoupled laterally from the substrate 17 which enters the recess 5 may be significantly reduced by the reflection or absorption of said stray radiation at the layer 11.

Alternatively, the extensive light-emitting element 3 may be applied with the substrate 17 to the electronic device 20, wherein in this case the covering layer 9 terminates the extensive light-emitting element 3 in the emission direction. In this case, a sub-region 10a of the substrate is not covered by the organic layer sequence 25 and the non-luminous region 30 and is covered with the layer 11.

FIG. 1B shows a schematic side view of the extensive light-emitting element 3 on an electronic device 20 as in FIG. 1A with the difference that the side faces of the substrate 17 facing the recess 5 are beveled. The bevel advantageously makes it possible for more light also to be emitted in the emission direction at the side faces, which additionally reduces the proportion of stray radiation in the recess 5. The bevels are located over the non-luminous region 30, in which no light is emitted. The side faces of the substrate 17 facing the recess 5 are thus further away from the middle of the recess 5, whereby less scattered light reaches the lower region of the recess 5. The recess 5 in the extensive light-emitting element 3 may therefore be smaller and the light-emitting area of the extensive light-emitting element 3 larger than in the example of FIG. 1A.

As in the exemplary embodiment of FIG. 1A it is also possible here for the arrangement of substrate 17 and covering layer 9 in the extensive light-emitting element 3 to be swapped. Then the side faces of the covering layer 9 are beveled.

FIG. 1C shows a schematic side view of the extensive light-emitting element 3 on an electronic device 20 as in FIG. 1A, with the difference that the side faces of the non-luminous region 30 and of the substrate 17 facing the recess 5 terminate flush with the side faces of the recess 5, such that the recess is of equal size throughout the extensive light-emitting element 3.

Furthermore, a non-transparent cover 19 in the form of a ring has been inserted into the round recess 5, such that the side faces of the extensive light-emitting element 3 which face the recess 5 are covered at least in part by the ring 19 and the ring 19 rests on the extensive light-emitting element 3 in such a way as to partly cover the substrate 17. The cover 19 prevents stray radiation from being outcoupled out of the covered regions in the recess 5.

As in the exemplary embodiment of FIG. 1A it is also possible here for the arrangement of substrate 17 and covering layer 9 in the extensive light-emitting element 3 to be swapped.

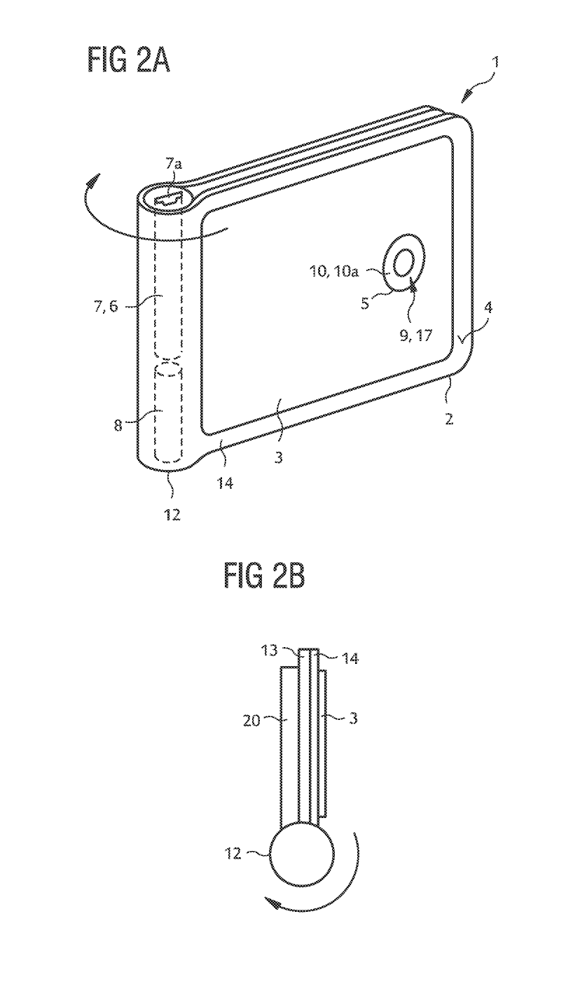

FIG. 2A shows a first exemplary embodiment of a flash apparatus 1 described here, in an external view. The flash apparatus 1 comprises a housing 2, wherein an extensive light-emitting element 3 is applied on an emission side 4. The flash apparatus 1 comprises a recess 5, which extends on the emission side 4 of the housing 2 through the housing and the extensive light-emitting element 3. The emission side 4 of the housing 2 comprises, for example, a lid plate 14. The lid plate 14 may be folded round by preferably 360°, for example, by means of a hinge 12 to close the housing, such that, when the housing is closed, the extensive light-emitting element 3 is located on an inside of the housing 2.

The hinge 12 may, for example, contain synchronization electronics 6 with an interface 7a and an energy storage unit 8. Furthermore, the synchronization electronics 6 may contain at least one further interface, in order to connect and synchronize an electronic device, which, for example, comprises a camera with integrated flash, with the flash apparatus 1. The interface 7a, for example, comprises a USB interface, wherein the interface 7a may be used to charge the energy storage unit 8.

Synchronization of an electronic device inserted into the housing may proceed, for example, in that the synchronization electronics 6 receive an audio signal and/or a digital signal pattern from the electronic device for synchronization. It is moreover possible for the electronic device inserted into the housing and connected with the synchronization electronics 6 to be charged via the interface 7a and to be connected to an external device, for example, to a computer, and thus to be controlled.

The recess 5 is, for example, circular in form, at the position of a camera of an electronic device insertable into the housing. The recess 5 in the OLED 3 here has a larger diameter in an upper region of the OLED 3 than in a lower region of the OLED, whereby in a plan view onto the recess 5 a sub-region 10 of the covering layer 9 can be seen at the margins of the recess 5. If the OLED is applied with the substrate 17 to the housing, a sub-region 10a of the substrate 17 can be seen at the margins of the recess 5. The exposed sub-region 10(a) is preferably covered with a layer which is, for example, reflective or absorbing. In this way, penetration into the recess in the housing of stray radiation outcoupled laterally from the OLED 3 is reduced markedly.

When the housing is open, the flash apparatus 1 may also be used as a torch or mood light.

FIG. 2B shows an electronic device 20 in a housing with a flash apparatus according to FIG. 2A, in a side view onto the housing.

On closure of the housing, the lid plate 14 with the OLED 3 on the emission side of the housing is folded by means of the hinge 12 by 360° around the electronic device 20, such that in a closed housing the OLED 3 is located on the inside of the housing and thus faces the electronic device 20. Advantageously both the electronic device 20 and the OLED 3 are thereby protected from external influences. When the lid plate 14 has been folded round, a back plate 13 of the housing remains on the back of the electronic device 20. The hinge 12 is, for example, located laterally next to the electronic device 20, whereby the thickness of the housing is not too greatly enlarged by the synchronization electronics and the energy storage unit.

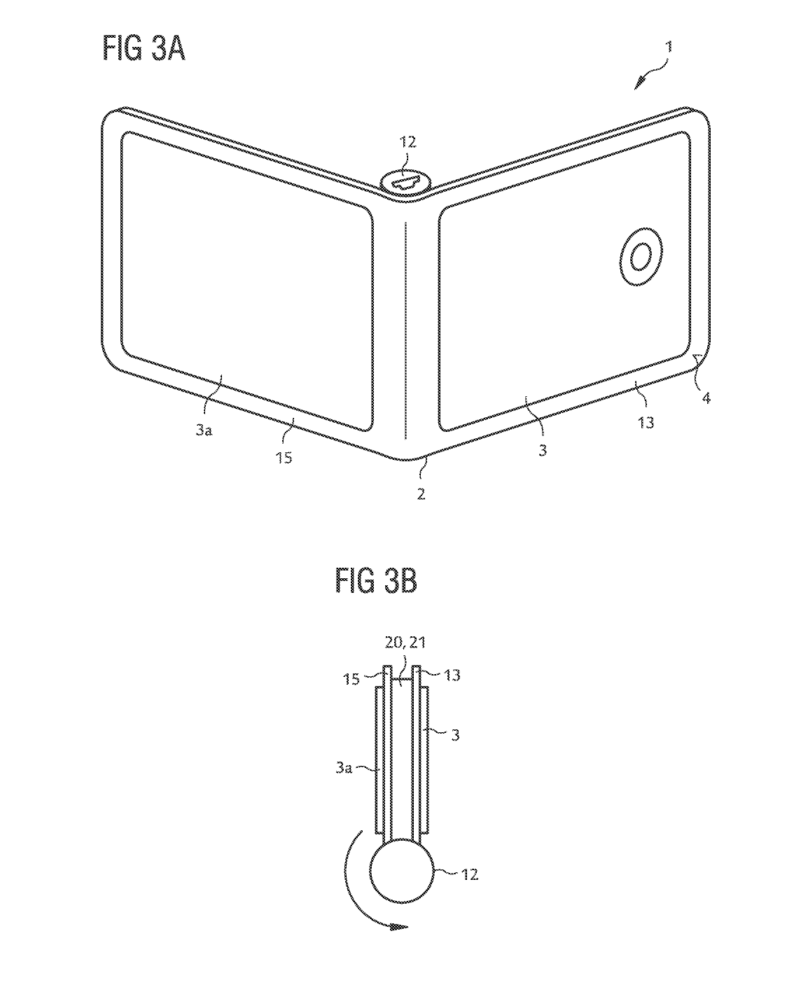

FIG. 3A shows a further exemplary embodiment of a flash apparatus 1 described here, in an external view similar to FIG. 2A, wherein the difference from FIG. 2A lies in the embodiment of the lid plate of the housing. The housing 2 comprises a lid 15 which may be folded round by means of the hinge 12, which lid, when the housing 2 is closed, forms the cover for the front of an electronic device to be enclosed by the housing and lies opposite the back plate 13 with regard to the inside of the housing. The back plate 13 forms an emission side 4 of the housing 2 and comprises an extensive light-emitting element 3 on the outside. The lid 15 advantageously likewise forms an emission side of the housing and comprises on the outside remote from the housing a further extensive light-emitting element 3a, in particular a further OLED. The further OLED 3a in this case preferably does not comprise any recesses. When opening the housing 2, the lid 15 is folded round by 180°, such that the further OLED 3a on the lid 15 is oriented in the emission direction of the emission side 4 of the housing 2 and is arranged next to the OLED 3. In this way, the emission area of the flash apparatus 1 is advantageously greatly enlarged, preferably doubled. An enlarged emission area markedly reduces glare for the people being photographed and the hard shadow effect.

FIG. 3B shows an electronic device 20 in a housing with a flash apparatus according to FIG. 3A, in a side view onto the housing. When the housing is closed, an electronic device 20 is enclosed by the housing with the back plate 13 and the lid 15 preferably in a manner conformed to the shape of the device. The electronic device 20 may furthermore comprise a mobile data processing and/or telecommunication device 21. On opening of the housing, the lid 15 is preferably folded round the hinge 12 by 180°. Furthermore, functional characteristics, operation and handling as well as optical and esthetic properties such as, for example, the design of the electronic device 20 are advantageously not impaired by the housing applied thereto but rather are advantageously improved and optimized.

When the OLEDs 3 and 3a are switched off, the housing may be used as a make-up mirror, due to a reflective effect. Furthermore, due to different color designs of the OLEDs, when they are switched off the esthetic appearance of the electronic device 20 may advantageously be optimized. By means of the interface of the synchronization electronics, both OLEDs 3a and 3 may be synchronized with the electronic device 20, such that the two OLEDs 3a and 3 function as a single flash. To this end, the synchronization electronics may adapt the necessary light output per unit area, for example, to external light conditions, camera sensitivity or the level of charge of the energy storage unit.

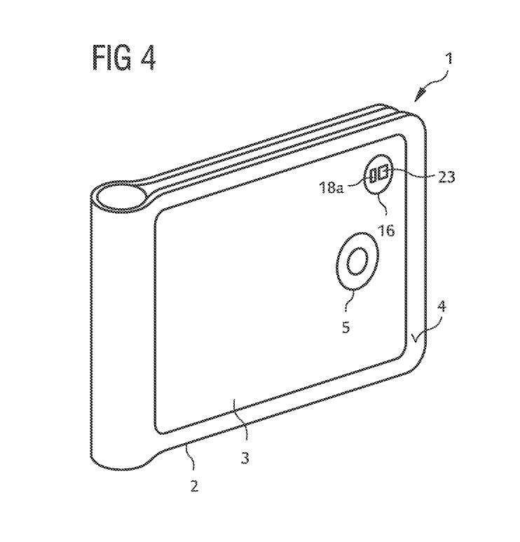

FIG. 4 shows a further exemplary embodiment of a flash apparatus 1 described here, in an external view similar to FIG. 2A. Unlike in FIG. 2A, the housing 2 comprises, in addition to the recess 5, a further recess 16 on the emission side 4 of the housing 2, wherein the recess 16 passes through the housing 2 and the OLED 3. The recess 16 is formed at a position at which an electronic device to be enclosed by the housing comprises an internal flash 23. A light sensor 18a is enclosed in the recess 16. It is thus advantageously possible, in addition to the flash of the extensive light-emitting element 3, to use the internal flash 23 of a camera inserted in the housing 2. In particular, triggering of the flash of the internal flash 23 is followed immediately by triggering of the flash of the OLED 3 and superimposition of the two flashes.

FIG. 5 shows an embodiment of the extensive light-emitting element 3 of the flash apparatus from FIG. 4 in a rear view, wherein a light sensor 18 is not located within a recess 16, as in FIG. 4, but rather is mounted on the surface of the organic light-emitting layer sequence facing the housing and is integrated into the OLED 3 in a sub-region around the recess 16 as an organic light sensor.

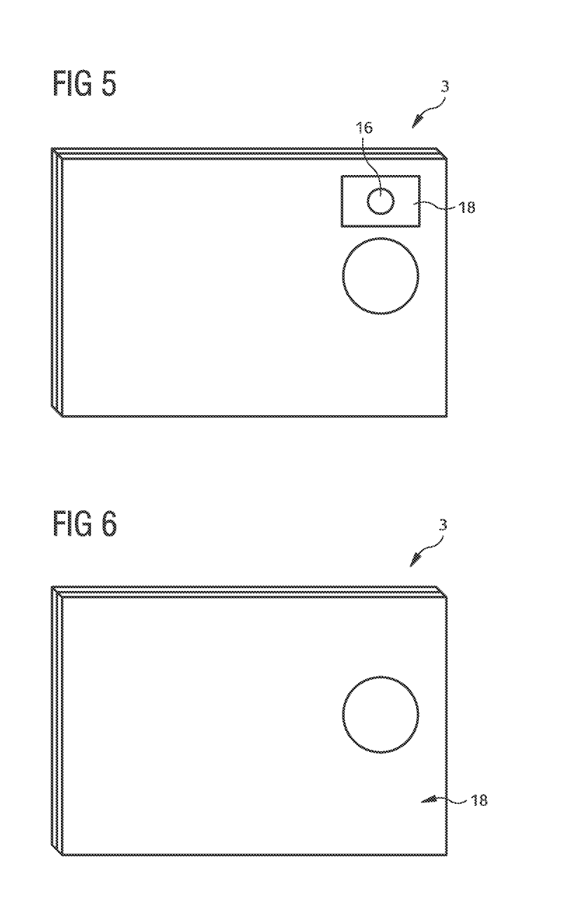

FIG. 6 shows an embodiment of the extensive light-emitting element 3 of the flash apparatus as in FIG. 5, wherein the light sensor 18 extends over the entire surface, facing the housing, of the organic light-emitting layer sequence and is integrated into the OLED 3 as an organic light sensor. The internal camera flash may thereby advantageously be detected by the light sensor 18 in a manner independent of the manufacturer of the electronic device to be inserted. In this case, no further recess is necessary.

The description made with reference to exemplary embodiments does not restrict the invention to these embodiments. Rather, the invention encompasses any novel feature and any combination of features, including in particular any combination of features in the claims, even if this feature or this combination is not itself explicitly indicated in the claims or exemplary embodiments.

1-17. (canceled)

18. An extensive light-emitting element for a flash apparatus, the extensive light-emitting element comprising:
at least one OLED, wherein the OLED comprises an organic light-emitting layer sequence arranged between a substrate and a covering layer, and wherein the organic light-emitting layer sequence comprises a recess in a region of the extensive light-emitting element.

19. The extensive light-emitting element according to claim 18, wherein the recess extends through the substrate, the organic light-emitting layer sequence and the covering layer of the OLED.

20. The extensive light-emitting element according to claim 19, wherein the recess is larger in the substrate and in the organic light-emitting layer sequence than in a region of the covering layer, or the recess is larger in the covering layer and in the organic light-emitting layer sequence than in a region of the substrate such that a sub-region of the covering layer or of the substrate adjoining the recess in the covering layer or the substrate is not covered by the organic light-emitting layer sequence.

21. The extensive light-emitting element according to claim 20, wherein within the recess the sub-region of the covering layer or the sub-region of the substrate is covered with a layer which is reflective or absorbing.

22. The extensive light-emitting element according to claim 18, wherein the substrate or the covering layer follows the organic light-emitting layer sequence in an emission direction, and side faces of the substrate or the covering layer facing the recess are beveled.

23. The extensive light-emitting element according to claim 18, further comprising a non-transparent cover applied at least to side faces of the extensive light-emitting element, the side faces facing the recess.

24. The extensive light-emitting element according to claim 18, wherein a light sensor is arranged in a further recess, wherein the further recess extends at least through the organic light-emitting layer sequence in a further region of the extensive light-emitting element.

25. The extensive light-emitting element according to claim 18, wherein at least one light sensor is arranged on a surface of the organic light-emitting layer sequence, and wherein the at least one light sensor faces away from an emission direction of the extensive light-emitting element.

26. The extensive light-emitting element according to claim 25, wherein the at least one light sensor wholly or partially covers the surface of the organic light-emitting layer sequence facing away from the emission direction of the extensive light-emitting element.

27. A flash apparatus comprising:
the extensive light-emitting element according to claim 18; and
a housing,
wherein the extensive light-emitting element is arranged on an emission side of the housing, and wherein the housing comprises a recess in the region of the recess in the extensive light-emitting element.

28. The flash apparatus according to claim 27, further comprising synchronization electronics with at least one interface and at least one energy storage unit, wherein the synchronization electronics and the at least one energy storage unit are enclosed in the housing.

29. The flash apparatus according to claim 28, wherein the synchronization electronics are designed to control the at least one energy storage unit and to synchronize at least one camera inserted into the housing with the flash apparatus.

30. The flash apparatus according to claim 28, wherein an audio signal pattern and/or a digital signal pattern may be received via the at least one interface of the synchronization electronics to synchronize the flash apparatus.

31. The flash apparatus according to claim 27, wherein the housing is a case or protective sleeve.

32. The flash apparatus according to claim 27, wherein the housing is configured to be opened and closed by folding, wherein the emission side of the housing with the extensive light-emitting element mounted thereon is arranged on a lid plate of the housing, wherein the lid plate is turnable so that the extensive light-emitting element is located on an inside of the housing when the housing is closed.

33. The flash apparatus according to claim 27, wherein the housing is configured to be opened and closed by folding, wherein a further extensive light-emitting element is located on a lid of the housing, and wherein the lid may be folded round on opening of the housing such that a lid face of the lid is oriented in an emission direction of the emission side of the housing.

34. An electronic device comprising:
the flash apparatus according to claim 27; and
a mobile data processing and/or telecommunication device which comprises
an integrated camera.

35. An extensive light-emitting element for a flash apparatus, the extensive light-emitting element comprising:
at least one OLED, wherein the OLED comprises an organic light-emitting layer sequence arranged between a substrate and a covering layer,
wherein at least the organic light-emitting layer sequence comprises a recess in a region of the extensive light-emitting element,
wherein a light sensor is arranged in a further recess, wherein the further recess extends at least through the organic light-emitting layer sequence in a region of the extensive light-emitting element, or
wherein at least one light sensor is arranged on a surface of the organic light-emitting layer sequence, and wherein the at least one light sensor faces away from an emission direction of the extensive light-emitting element.
